(19) United States
(12) Patent Application Publication
(10) Pub. No.: US 2017/0084810 A1
(43) Pub. Date: Mar. 23, 2017

(54) Thermally Conductive Circuit Board Substrate and Method of Manufacture

(71) Applicant: Raul A. Klein, Las Vegas, NV (US)

(72) Inventor: Raul A. Klein, Las Vegas, NV (US)

(21) Appl. No.: 15/369,762

(22) Filed: Dec. 5, 2016

(51) Int. Cl. H01L 33/64; H01L 21/48; H05K 3/10; H05K 1/02; H05K 3/12

(52) U.S. Cl. CPC H01L 33/647; H01L 33/641; H05K 1/021; H05K 3/1275; H05K 3/101; H01L 33/642; H01L 21/4846; H01L 21/4871; H05K 2201/10106

(57) ABSTRACT

A thermally conductive efficient substrate for use in an electrical circuit board assembly (ECBA) preferably having at least one LED component. The substrate is constructed of a thermally conductive efficient material such that the substrate functions both as a substrate and as a heat sink for the PCB. The substrate allows a PCB to function without a dedicated auxiliary heat sink. The substrate preferably includes a plurality of raised pads formed such that open channels are formed therebetween, and such that the upper surfaces of the pads are preferably substantially coplanar. Such intra-pad channels facilitate heat transfer and cooling of the substrate and the ECBA.

### FIELD OF THE INVENTION

The present invention relates to electrical circuit boards such as those circuit boards used to perform an electrical function such as lighting a light emitting diode (LED) and more particular, to thermally conductive efficient electrical circuit board substrates and methods for manufacturing the same.

### BACKGROUND OF THE INVENTION

An electrical circuit board is a board that mechanically supports and electrically connects electrical components using electrically conductive tracks, pads, and other features on a non-conductive substrate. Such circuit boards are often referred to as printed circuit boards or PCBs and typically include electrically conductive tracks that have been etched from copper sheets that have been laminated onto a non-conductive substrate (see Appx A). Such etching process requires masking preparation (adding to the cost of the PCB) and typically requires the use of toxic chemicals during the etching process. Such electrical circuit boards and more especially PCBs are known in the art and have broad application in a variety of electrical appliances. Examples of such circuit boards are disclosed in the following list of US patents and applications, all of which are expressly incorporated herein by reference: U.S. Pat. No. 8,309,855 to Chung, U.S. Pat. No. 9,204,547 to Hughes, US 2009/0308639 to Chung, US 2014/0313684 to Hughes, US 2015/0351229 to Lee et al, US 2016/0020500 to Matsuda, and US 2016/0057853 to Zacharko et al. Further, it is known to provide light emitting diodes or LEDs as an integrated component of such PCBs (see Appx B). It is also known that such LEDs generate significant heat and that such heat can be detrimental to the function and life of such LED PCBs. Accordingly, the management and dissipation of such heat is an important factor in the design of an LED PCB (see Appx C). The management of heat in prior art PCB's typically includes the use of one or more heat sinks in thermally conductive contact to the PCB substrate. An example of such management and dissipation of heat in an LED PCB is disclosed in US patent application 2016/0343916 to Klein which is expressly incorporated herein by reference.

### SUMMARY OF THE INVENTION

The present invention is a thermally conductive efficient substrate of an electrical circuit board assembly (ECBA) preferably having at least one LED component. The substrate is constructed of a thermally conductive efficient material such that the substrate functions both as a substrate for a PCB in substantially conventional fashion and as a heat sink for the PCB. Thus the disclosed substrate allows a PCB to function without (and eliminates the need for) a dedicated auxiliary heat sink. The substrate preferably includes a plurality of raised pads formed such that open channels are formed therebetween, and such that the upper surfaces of the pads are preferably substantially coplanar. Such intra-pad channels facilitate heat transfer and cooling of the substrate and the ECBA. Further, such raised pads provide for alternate methods of electrically conductive track manufacturing so as to avoid the necessity of chemical etching which requires the use of hazardous toxic chemicals. Such alternate methods of electrically conductive track construction include adhesive conductive sheet application, conductive ink screen printing, and conductive ink painting (via rolling or dipping/stamping).

### DESCRIPTION OF DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is a trimetric view of the ECBA in an assembled configuration (looking down on the top of the ECBA);

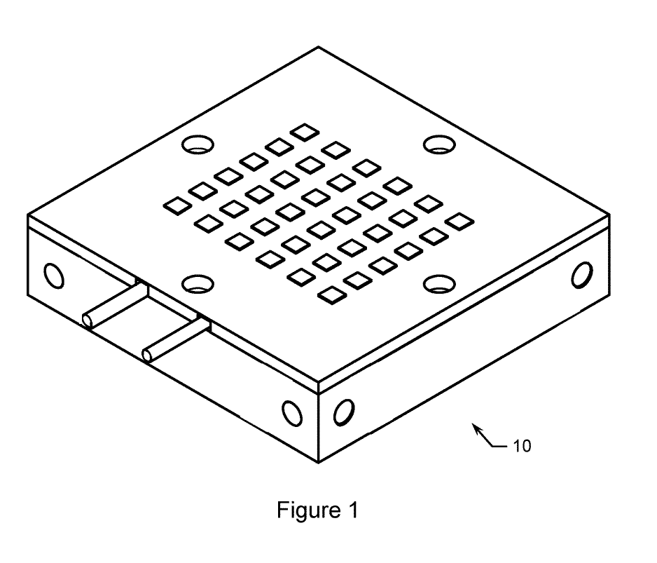

FIG. 2 is a trimetric view of the ECBA in an assembled configuration (looking up at the bottom of the ECBA);

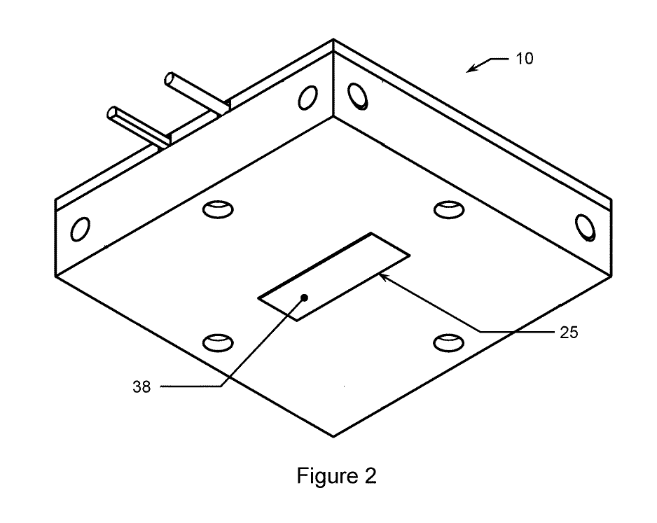

FIG. 3 is an exploded trimetric view of the ECBA in a disassembled configuration but with the substrate subassembly shown assembled;

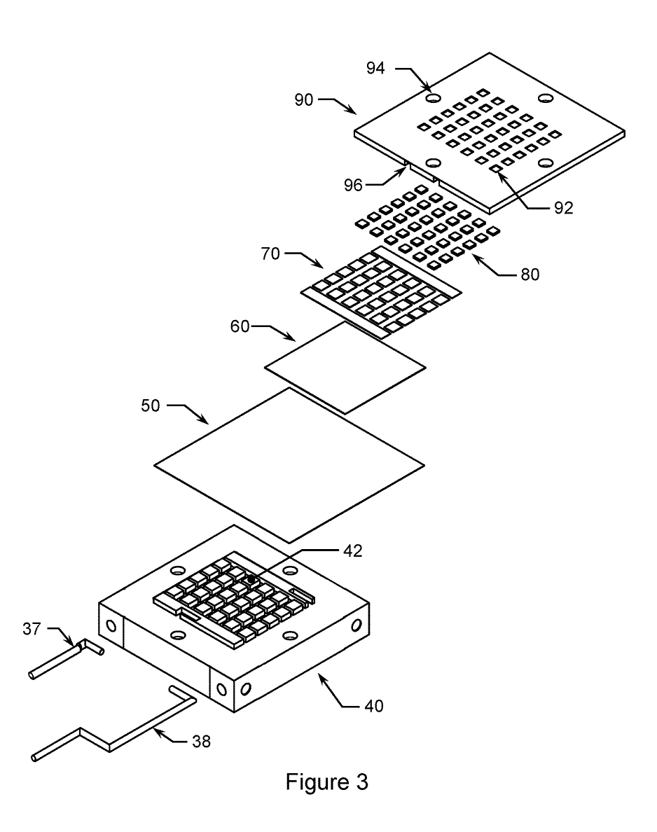

FIG. 4 is an exploded trimetric view of the substrate subassembly;

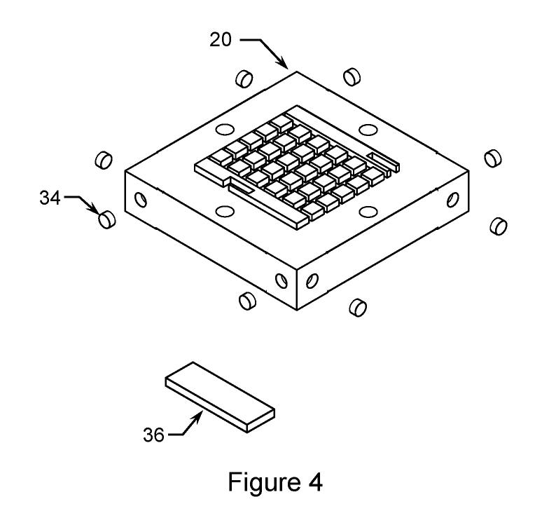

FIG. 5 is a trimetric view of the substrate, and;

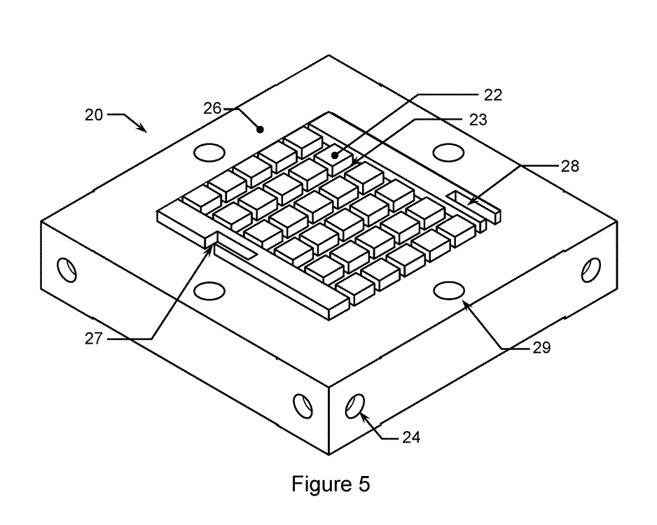

FIG. 6 is a trimetric view of an alternate substrate.

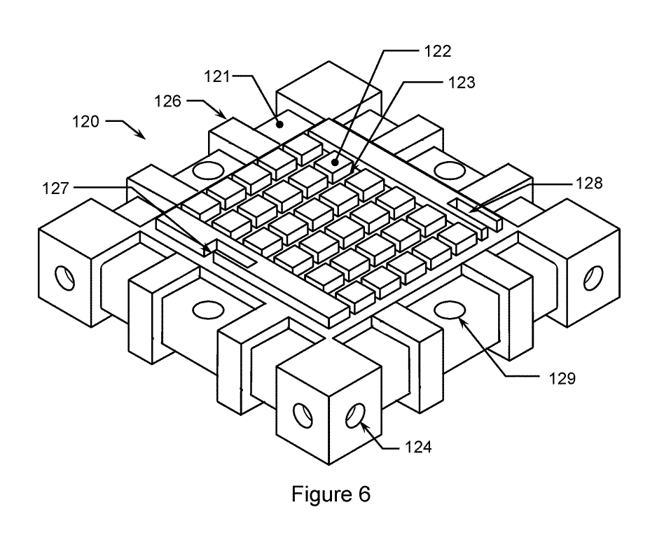

### DETAILED DESCRIPTION OF THE INVENTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are included to provide a thorough understanding of embodiments of the invention. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the invention.

In order to facilitate the understanding of the present invention in reviewing the drawings accompanying the specification, a feature table is provided below. It is noted that like features are like numbered throughout all of the figures.

FEATURE TABLE

| # | Feature | # | Feature |
|---|---|---|---|
| 10 | Electrical Circuit Board | 20 | Substrate |
| | Assembly (ECBA) | | |
| 22 | Raised pad | 23 | Channel |
| 24 | Quick connect magnet | 25 | Mounting magnet |
| | reception hole | | reception pocket |
| 27 | Positive lead wire | 28 | Negative lead wire |
| | reception slot | | reception slot |
| 29 | Mounting hole | 34 | Quick connect magnet |
| 36 | Mounting magnet | 37 | Positive lead wire |
| 38 | Negative lead wire | 40 | Substrate subassembly |
| 42 | Electrically conductive | 50 | Thermally conductive |
| | track | | material |
| 60 | Dielectric material | 70 | Electrically conductive |
| | | | material |
| 80 | LED chips | 90 | Cover |
| 92 | LED chip opening | 94 | Mounting hole |
| 120 | Substrate | 121 | Tech pocket |
| 122 | Raised pad | 123 | Channel |
| 124 | Quick connect magnet | 125 | Mounting magnet |
| | reception hole | | reception pocket |
| 126 | Heat radiating cooling fin | 127 | Positive lead wire |
| | | | reception slot |
| 128 | Negative lead wire | 129 | Mounting hole |
| | reception slot | | |

Referring now to the drawings, in a preferred embodiment the invention is an electrical circuit board assembly 10 (ECBA 10) adapted to be constructed without etching and for use in providing light from an LED while efficiently dissipating heat from the LED comprising a substrate subassembly 40, a plurality of LED chips 80, and a cover 90. LED chips 80 define substantially standard LED chips that are adapted to be electrically connected to electrically conductive tracks and are adapted to emit light when electrically energized. Cover 90 comprises a generally flat rectangular nonconductive cover having a plurality of LED chip openings 92, and a plurality of mounting holes 94.

Substrate subassembly 40 comprises substrate 20, a plurality of quick connect magnets 34, mounting magnet 36, positive lead wire 37, negative lead wire 38, thermally conductive material 50, dielectric material 60, and electrically conductive material 70.

Substrate 20 defines a preferably monolithic substantially irregular but generally cubic shaped substrate comprised of non-electrically conductive but thermally efficient material, and more preferably, a material having a thermal conductivity rating of approximately 1 watt per meter kelvin (or 1 W/M·K) or more. An exemplary material is Alumide—a material comprising nylon filled with aluminum dust (see Appx D). Alternatively, materials that are functionally similar to Alumide and preferably comprise composite materials of a combination of a plastic material having metal or carbon particles interspersed therein are also contemplated. The selected material should be capable of being formed into a substrate for a PCB assembly that is capable of performing both the function of a substrate for the PCB assembly and a heat sink for a PCB assembly without the use of a dedicated auxiliary heat sink, such that the PCB assembly is capable of functioning as it would otherwise if it had at least one discrete auxiliary heat sink. Substrate 20 includes a plurality of preferably substantially coplanar raised pads 22, a plurality of open channels 23 formed therebetween, a plurality of quick connect magnet reception holes 24, a mounting magnet reception pocket 25, a positive lead wire reception slot 27, a negative lead wire reception slot 28, and a plurality of mounting holes 29. Substrate 20 is preferably manufactured by use of an additive processes such as creating substrate 20 by 3D printing, selective laser sintering or fused deposition modeling (see Appx E). It is noted that rather than mere rudimentary shapes such as a generally cubic shape, substrate 20 may be generally formed in virtually limitless shapes including spheres, animals, cars, buildings, people, and abstract shapes (i.e. waves, twisting objects, and asymmetrical objects). Regardless of the overall shape in which substrate 20 is formed, substrate 20 retains the aforementioned features and functions of substrate 20. Further, regardless of the overall shape in which substrate 20 is formed, other members of ECBA 10 are like geometrically adapted so as to fit to and function with substrate 20.

Quick connect magnet 34 defines a substantially solid cylindrical shaped member constructed preferably of a ferromagnetic material. Mounting magnet 36 defines a substantially solid cubic shaped member constructed preferably of a ferromagnetic material. Positive lead wire 37 and negative lead wire 38 define electrically conducting lead wires that include an insulting outer coating. Thermally conductive material 50 defines an adhesive laminate sheet of thermally conductive material but may alternately take the form of a thermally conductive tape, a thermally conductive spray, or a thermally conductive paint. Dielectric material 60 defines an adhesive laminate sheet of dielectric material but may alternately take the form of a dielectric tape, a dielectric spray, or a dielectric paint. Electrically conductive material 70 defines a preferably frangible adhesive laminate sheet of electrically conductive material but may alternately take the form of electrically conductive ink or paint.

Substrate subassembly 40 is assembled such that thermally conductive material 50 is adhered to or applied to substantially all of the outer surfaces of substrate 20, and especially to the surfaces of raised pads 22 and open channels 23. Dielectric material 60 is then adhered to or applied to substantially all of the outer surfaces of substrate 20. Without masking or etching, electrically conductive material 70 is adhered to or applied to the upper surfaces of raised pads 22. Electrically conductive material 70 is preferably applied to raised pads 22 by pressing electrically conductive material 70 as a frangible adhesive laminate sheet against raised pads 22 and then pulling electrically conductive material 70 as a frangible adhesive laminate sheet off of substrate 20. When electrically conductive material 70 as a frangible adhesive laminate sheet is pulled off of substrate 20, those areas of the laminate sheet that were pressed into contact with raised pads will remain of the upper surfaces of raised pads 22, and the remainder of the laminate sheet will be removed from substrate 20. These remaining portions of electrically conductive material 70 as a frangible adhesive laminate sheet that remain adhered to the upper surfaces of raised pads 22 form electrically conductive tracks 42. Alternatively, electrically conductive material 70 in the form of electrically conductive ink is screen printed on only the upper surfaces of raised pads 22. These screen printed upper surfaces of raised pads 22 form electrically conductive tracks 42. Further alternatively, electrically conductive material 70 in the form of electrically conductive ink or paint is applied on only the upper surfaces of raised pads 22 by rolling electrically conductive material 70 in the form of electrically conductive ink or paint onto the upper surfaces of raised pads 22 or by pressing the upper surfaces of raised pads 22 against a member (such as a blotter) having conductive material 70 in the form of electrically conductive ink or paint thereon, the latter method being analogous to “inking” a rubber stamp having raised lettering by pressing the rubber stamp onto an ink pad. These painted upper surfaces of raised pads 22 form electrically conductive tracks 42.

Substrate subassembly 40 is further assembled such that quick connect magnets 34 are affixed into quick connect magnet reception holes 24, mounting magnet 36 is affixed to mounting magnet reception pocket 25, positive lead wire 37 is affixed in positive lead wire reception slot 27 and electrically connected to an electrically conductive track 42, and negative lead wire 38 is affixed in negative lead wire reception slot 28 and electrically connected to an electrically conductive track 42.

ECBA 10 is assembled such that LED chips 80 are connected to a first electrically conductive track 42 on a first end and to a second electrically conductive track 42 on a second end, and such that an electrical circuit is formed from positive lead wire 37, through LED chips 80 and electrically conductive tracks 42, and to negative lead wire 38. Cover 90 is positioned on substrate subassembly 40 such that LED chips 80 are positioned in LED chip openings 92. ECBA 10 is secured by affixing fasteners into mounting holes 29, 32 and 94.

In practice, when assembled ECBA 10 is electrically energized via lead wires 37 and 38, light will emit from LEDs 80 while ECBA 10 is cooled at least in part by air flowing through open channels 23 and through the effect of substrate 20 drawing heat away from other components of ECBA 10. ECBA 10 may be easily and quickly positioned on a metallic surface by means of mounting magnet 36 being placed in magnetically adhering contact to such metallic surface. Further, a plurality of ECBAs 10 may be magnetically connected together by placing quick connect magnets 34 of a first instance of ECBA 10 into magnetic contact with quick connect magnets 34 of a second instance of ECBA 10. In such arrangement of a plurality of ECBAs 10, ECBAs 10 are preferably arranged such that ECBAs 10 are electrically connected in series by means of lead wires of the various ECBAs 10.

In an alternate embodiment, substrate 120 is substituted for substrate 20 in ECBA 10. Substrate 120 defines a preferably monolithic substantially irregular but generally cubic shaped substrate comprised of non-electrically conductive but thermally efficient material, and more preferably, a material having a thermal conductivity rating of approximately 1 watt per meter kelvin (or 1 W/M·K) or more. An exemplary material is Alumide—a material comprising nylon filled with aluminum dust (see Appx D). Alternatively, materials that are functionally similar to Alumide and preferably comprise composite materials of a combination of a plastic material having metal or carbon particles interspersed therein are also contemplated. The selected material should be capable of being formed into a substrate for a PCB assembly that is capable of performing both the function of a substrate for the PCB assembly and a heat sink for a PCB assembly without the addition of an auxiliary heat sink, such that the PCB assembly is capable of functioning as it would otherwise if it had at least one discrete auxiliary heat sink. Substrate 120 includes a plurality of “tech pockets” 121 (a tech pocket being a recess formed in the substrate and adapted to preferably at least partially conform to and receive an alternate and especially third party device such as an infrared sensor or a blue tooth radio chip, such that the third party device cooperatively electrically functions with a PCB assembly of which the substrate forms a component of), a plurality of preferably substantially coplanar raised pads 122, a plurality of open channels 123 formed therebetween, a plurality of quick connect magnet reception holes 124, a mounting magnet reception pocket 125, a plurality of heat radiating cooling fins 126, a positive lead wire reception slot 127, a negative lead wire reception slot 128, and a plurality of mounting holes 129. Substrate 120 is preferably manufactured by use of an additive processes such as creating substrate 20 by 3D printing, selective laser sintering or fused deposition modeling (see Appx E). It is noted that rather than mere rudimentary shapes such as a generally cubic shape, substrate 120 may be generally formed in virtually limitless shapes including spheres, animals, cars, buildings, people, and abstract shapes (i.e. waves, twisting objects, and asymmetrical objects). Regardless of the overall shape in which substrate 120 is formed, substrate 120 retains the aforementioned features and functions of substrate 120. Further, regardless of the overall shape in which substrate 120 is formed, other members of ECBA 10 are like geometrically adapted so as to fit to and function with substrate 120.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An ECBA having a thermally conductive efficient substrate wherein said substrate functions as both a substrate and a heat sink for said ECBA, and wherein said ECBA does not include an auxiliary dedicated heat sink.

2. The substrate of claim 1, wherein said substrate is formed from a plastic composition having at least one of metal particles and carbon particles interspersed therein.

3. The substrate of claim 1, wherein said substrate is formed from Alumide.

4. The substrate of claim 1, wherein said substrate includes at least one of a plurality of fins protruding therefrom and adapted so as to radiate heat and cool said ECBA, and at least one tech pocket.

5. The substrate of claim 1, wherein said substrate has a thermal conductivity value of at least 1 watt per meter kelvin.

6. The substrate of claim 1, wherein said substrate is manufactured via an additive manufacturing process.

7. The substrate of claim 1, wherein said additive manufacturing process defines at least one of 3D printing and selective laser sintering.

8. A thermally conductive efficient ECBA substrate formed from a composition having at least one of metal particles and carbon particles interspersed therein.

9. The substrate of claim 8, wherein said substrate is formed from Alumide.

10. The substrate of claim 8, wherein said substrate includes at least one of a plurality of fins protruding therefrom and adapted so as to radiate heat and cool said ECBA, and at least one tech pocket.

11. The substrate of claim 8, wherein said substrate has a thermal conductivity value of at least 1 watt per meter kelvin.

12. The substrate of claim 8, wherein said substrate is manufactured via an additive manufacturing process.

13. The substrate of claim 8, wherein said additive manufacturing process defines at least one of 3D printing and selective laser sintering.

14. The substrate of claim 8, wherein said substrate functions as both a substrate and a heat sink for said ECBA, and wherein said ECBA does not include an auxiliary dedicated heat sink.

15. A method of manufacturing a thermally conductive efficient ECBA substrate comprising the steps of providing a composition having at least one of metal particles and carbon particles interspersed therein and forming an ECBA substrate via an additive manufacturing process.

16. The method of claim 15, wherein said additive manufacturing process defines at least one of 3D printing and selective laser sintering.

17. The method of claim 15, wherein said composition defines Alumide.

18. The method of claim 15, wherein said substrate includes at least one of a plurality of fins protruding therefrom and adapted so as to radiate heat and cool said ECBA, and at least one tech pocket.

19. The method of claim 15, wherein said substrate has a thermal conductivity value of at least 1 watt per meter kelvin.

20. The method of claim 15, wherein said substrate functions as both a substrate and a heat sink for said ECBA, and wherein said ECBA does not include an auxiliary dedicated heat sink.
